(19) United States
(12) Patent Application Publication
(10) Pub. No.: US 2015/0208789 A1
(43) Pub. Date: Jul. 30, 2015

(54) WEARABLE CONVERTIBLE CASE AND STAND FOR TABLET COMPUTERS

(71) Applicant: Sergejus Pylkovas, Palm Coast, FL (US)

(72) Inventor: Sergejus Pylkovas, Palm Coast, FL (US)

(21) Appl. No.: 14/165,549

(22) Filed: Jan. 27, 2014

(51) Int. Cl. A45F 3/02; H05K 5/02; A45C 11/00; G06F 1/16

(52) U.S. Cl. CPC A45F 3/02; G06F 1/163; H05K 5/0217; H05K 5/0239; A45C 11/00; A45C 2011/003

(57) ABSTRACT

The wearable convertible case allows for several ways of carrying a tablet computer and for using a tablet computer while standing up or sitting without the need to hold the computer with one or both hands. In addition, the case may be used as a stand to hold a tablet at an incline for easy operation when reading, typing, watching movies, etc. In the hands-free mode the case may be used, for example, when commuting by public transportation or for operation by students, medical personal, warehouse workers, journalists, etc. The case may be worn comfortably when walking, running, riding a bicycle or motorcycle when configured as a backpack or a “chest-pack”.

### FIELD OF THE INVENTION

This invention relates to carriers for tablet computers.

### BACKGROUND OF THE INVENTION

The invention of the tablet computer (the terms “tablet computer,” and “tablet” are used interchangeably in this document) has allowed users to input data through the display screen without the need of a mouse or keyboard. When operating the tablet without a desk, users are required to use their hands to hold the tablet while simultaneously interacting with it. This creates an inconvenient user experience and increases the chance of damage to the tablet in the event of a fall.

Solutions for hands-free tablet use have been proposed. For example, U.S. Pat. No. 2007/0051766 to Spencer, U.S. Pat. No. 2010/0006614 to McLean, and U.S. Pat. No. 5,639,004 to Carlton aim to provide hands-free support for tablets and notebook computers while standing.

U.S. Pat. No. 2007/0051766 to Spencer provides a hands-free support solution for tablets and notebook computers by utilizing two attachment points located midway on the sidewalls of the carrying case. The design utilizes a stability strap which extends between the two attachment points. This product is not designed as a lightweight, easy-to-use, tablet carrying device, but instead provides a robust carrier design for protecting and supporting tablets and notebook PCs.

U.S. Pat. No. 2010/0006614 to McLean provides a hands-free support solution for laptops, tablets PCs, ultra mobile PCs, and accessories by utilizing four attachment points; two attachment points are located on the top two corners, and two more attachment points are located close to the midway point on the sidewall of the carrying case. The design uses two straps, multiple components, and is intended as a universal carrier with sidewalls to hold mobile computers. In addition to providing hands-free support, the design provides improved protection, increased utility, and thermal management. The design does not utilize one strap as a mainstay to achieve functionality, cannot be used as a backpack, and is not streamlined for tablet use.

U.S. Pat. No. 5,639,004 to Carlton provides a hands-free support solution for notebook computers, tablet computers, personal digital assistants and printers, or a combination of small electronic device. The design utilizes four straps connected between a connection point on the user's back and the case. Two straps run from the connection point, above the shoulders, and to the case; two more straps run from the connection point, underneath the armpit, and to the case. The design is not focused on tablet use, requires a back connection point which makes use of the product awkward, and utilizes multiple straps to achieve functionality.

None of the aforementioned designs are streamlined for tablet computers, nor provide a lightweight, easy-to-use, tablet case that converts between multiple carrying positions, a hands-free wearable platform, and a desktop stand.

### ADVANTAGES

Thus, the advantages of the design herein are:

extremely lightweight and compact design streamlined for tablet use;

multiple carrying configurations include across the chest, across the back as a backpack, around the shoulder and down the side of the body, or around the shoulder and across the body;

case can be converted into a stand that can hold the tablet in an upright or incline position on a flat surface;

case can be converted into a platform to support the tablet when the user is standing;

transitions between carrying modes, stand mode, and hands-free platform mode are quick and easy, taking seconds to perform.

### SUMMARY OF THE INVENTION

The product is designed for tablet computers and provides an extremely lightweight and easy-to-use solution for carrying a tablet in multiple configurations, using a tablet while standing or sitting without the need to hold the tablet with one or both hands, and as an incline stand to hold the tablet on a flat surface while reading, typing, watching movies, etc.

The product is a rectangular folio-type tablet case with attachment points at all four corners. The case has a flap that keeps the case closed and can be opened to reveal the tablet display. The flap can be positioned to support the tablet at an incline when on a flat surface.

A quickly adjustable strap can be attached in multiple configurations that allows the case to be carried over the shoulder, on the back as a backpack, or across the body. The case can also be configured to permit the user hands-free access to the tablet while standing.

### BRIEF DESCRIPTION OF THE DRAWINGS

FIG. 1 is a plane view of the carrying case in the closed configuration

FIG. 2 is a plane view of the carrying case with section one 12 of the flap opened.

FIG. 3 is a plane view of the carrying case with the entire flap 11 opened to reveal the interior of the case.

FIG. 4 is one embodiment of the carrying case in vertical standing mode.

FIG. 5 is a perspective view of the quickly adjustable strap.

FIG. 6 is a perspective view of a user equipped with the carrying case in over the shoulder configuration with the strap attached to the width side of the case.

FIG. 7 is one embodiment of the carrying case with the quickly adjustable strap attached in the diagonal configuration and worn across the back as a backpack.

FIG. 8 is one embodiment of the carrying case with the quickly adjustable strap attached in the diagonal configuration, and the case setup in hands-free platform mode buttressed by the body.

### DRAWINGS—REFERENCE NUMERALS

10 Case

11 Flap

12 Section one of the flap

13 Velcro® on section one of the flap

14 Velcro® on the platform of the case

15 Section two of the flap

16 Section three of the flap

17 Protective frame running around the interior perimeter of the platform

18 Slot for tablet insertion into the case

19 Attachment point one

20 Attachment point two

21 Attachment point three

22 Attachment point four

23 Adjustable strap

24 Cam buckle on the strap

25 Snap hooks on the strap

26 Rectangle platform of the case

27 Headphone port

28 Charger port

29 Speaker port

30 Volume and lock port

31 Camera port

32 Power button port

33 Microphone port

34 Bendable section between flap section three 16 and the platform 26

35 Bendable section between flap section one 12 and two 15

36 Bendable section between flap section two 15 and three 16

### DETAILED DESCRIPTION OF THE INVENTION

The invention disclosed herein is susceptible to embodiment in many different forms. The embodiments herein are preferred embodiments of the invention. The present disclosure is an example of the principles of the invention and does not limit the invention to the illustrated embodiments.

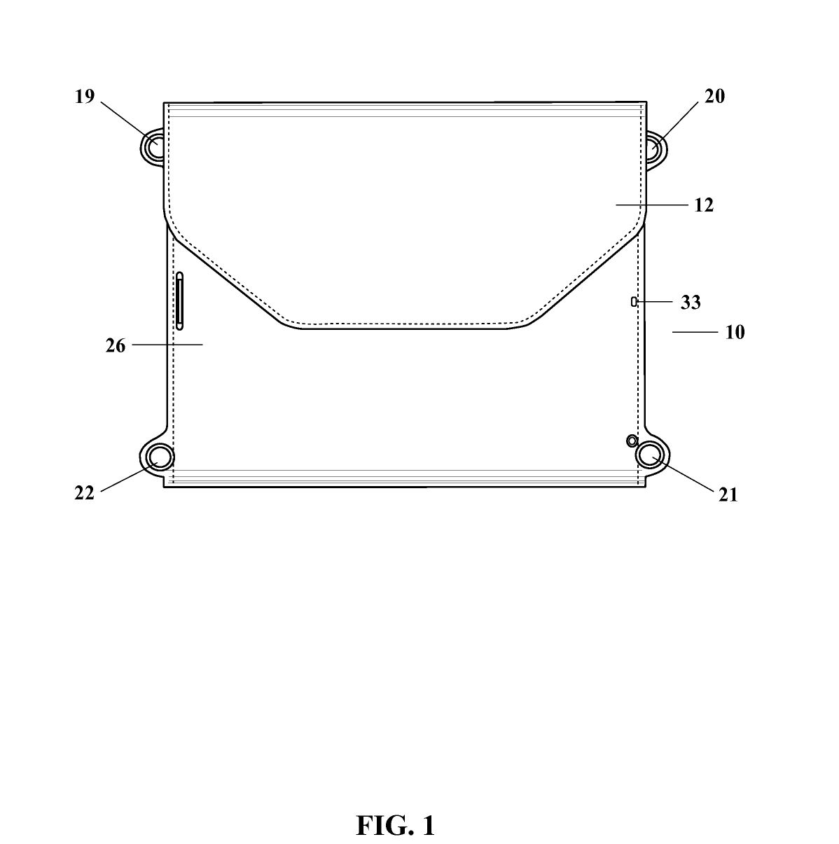

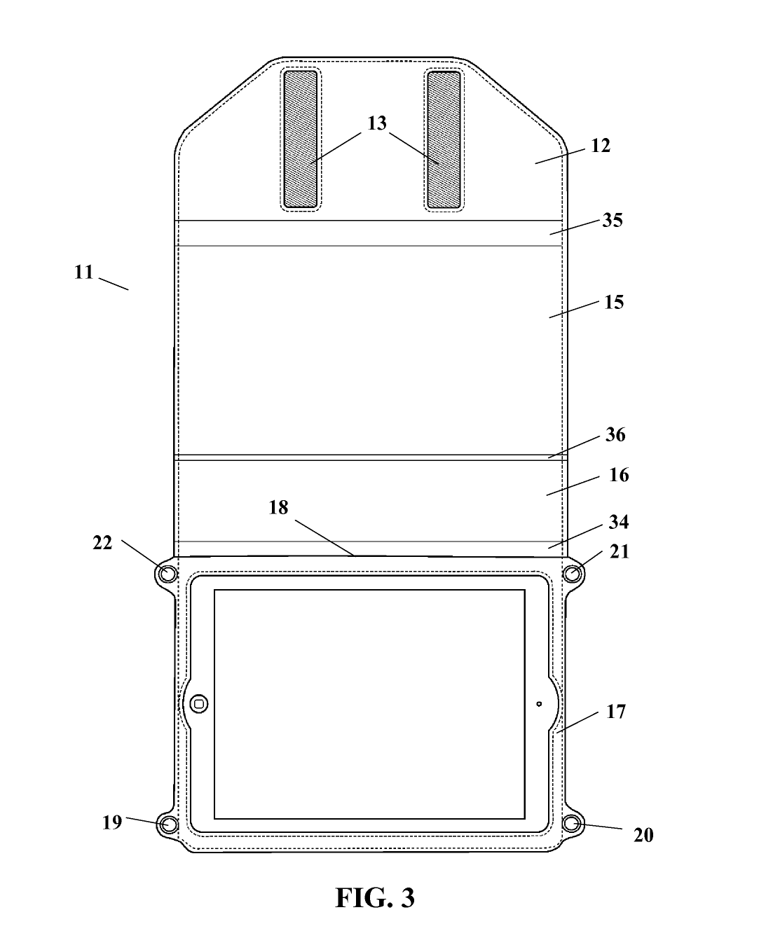

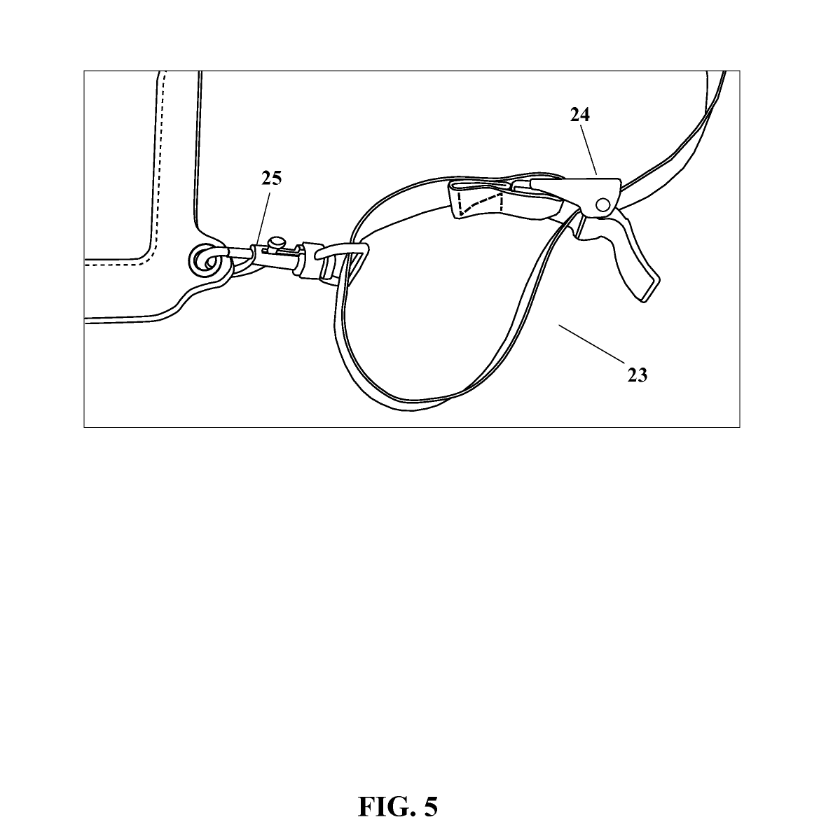

FIG. 1 shows the case 10 in the closed position. The case 10 is composed of a rectangle platform 26 having an interior and exterior portion, and a protective frame 17 (shown in FIG. 3) running around the interior perimeter of the platform. The platform 26 and protective frame 17 are joined to create a protective case to hold a tablet computer. Four grommets form corner attachment points (19, 20, 21, and 22) that are used in conjunction with a quickly adjustable strap 23 (shown in FIG. 5) to achieve multiple case configurations. The case may be used without the strap 23 as a folio-type case.

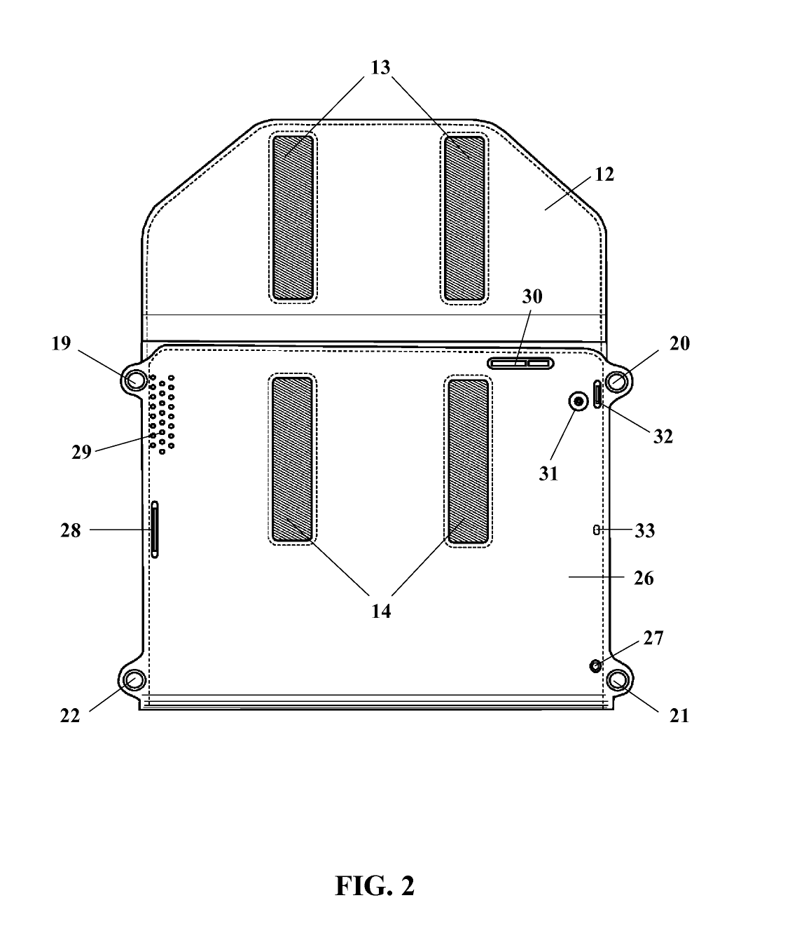

Referring to FIG. 2, the back side of the case has seven ports for general tablet use. On the bottom of the case, there is charger port 28 to allow the user to charge the tablet while inside the case, and a speaker port 29 to limit the interference of sound coming from the tablet. On the left side of the case, there is a volume and lock port 30 to allow the user access to the volume and lock functionality on the tablet. On the top of the case there is a camera port 31 to avoid blocking the tablet camera's view, a power button port 32 to give the user access to the tablet power button, a microphone port 33 to allow the tablet microphone to pick up sound, and a headphone port 27 to allow the user to use headphones with the tablet inside the case. The placement of the ports is not fixed and may be augmented to fit the required specifications for a particular tablet.

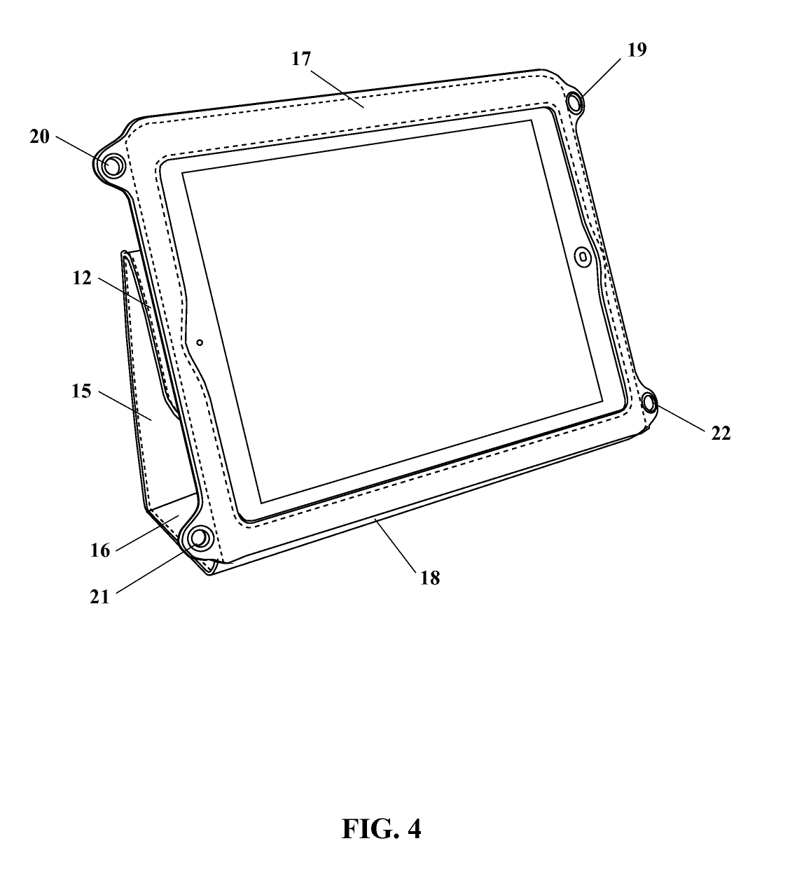

Referring to FIG. 3, the inside of the case is fitted with micro-fiber to keep the tablet free from damage. A flap 11 is positioned on the long side of the platform 26 and can be folded back to reveal the tablet display. The flap 11 is composed of three sections with bendable divisions (34, 35, and 36) between the sections. Flap section one 12 has Velcro® strips 13 that connect to the Velcro® strips on the back of the platform 14 (shown in FIG. 2). Section two 15 keeps the tablet screen protected and serves as a vertical support when in stand mode (shown in FIG. 4). Section three 16 keeps the screen protected and serves as a horizontal support when in stand mode (shown in FIG. 4). The protective frame 17 is composed of hard material bound in soft material to keep the tablet protected. The tablet is inserted into the case in an envelope style method through a slot 18 located on the long side of the platform 26 between the platform 26 and the protective frame 17.

Referring to FIG. 5, the length of the strap 23 is quickly adjustable by use of a sliding cam buckle 24. The strap 23 is composed of either nylon or polyester webbing. To adjust the length, the user opens the cam buckle 24, and slides the cam buckle 24 along the strap webbing for quick adjustability. There are two quick release snap hooks 25 that attach to any of the four attachment points (19, 20, 21, or 22).

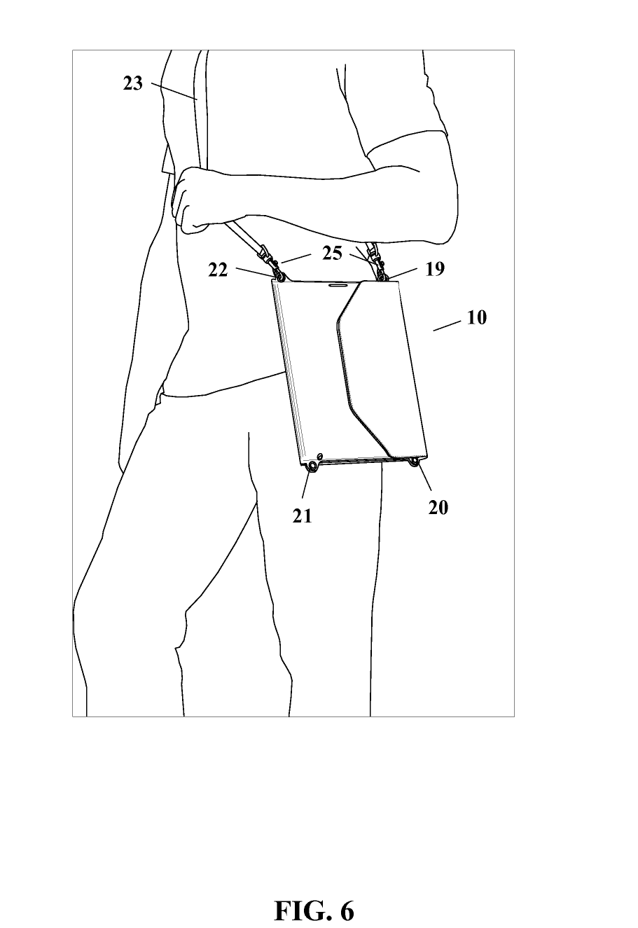

The adjustable strap 23 connects to two of the four attachment points 19, 20, 21, or 22 to allow the user multiple carrying positions, and a hands-free platform mode. When the strap 23 is connected to attachment points 19 and 22, or 20 and 21, the case can be carried in the vertical position in over the shoulder and down the side of the body, or over the shoulder and across the body carrying positions (shown in FIG. 6). Both positions can be achieved with the case hanging in the horizontal position when the strap is attached to attachment points 19 and 20, or 21 and 22.

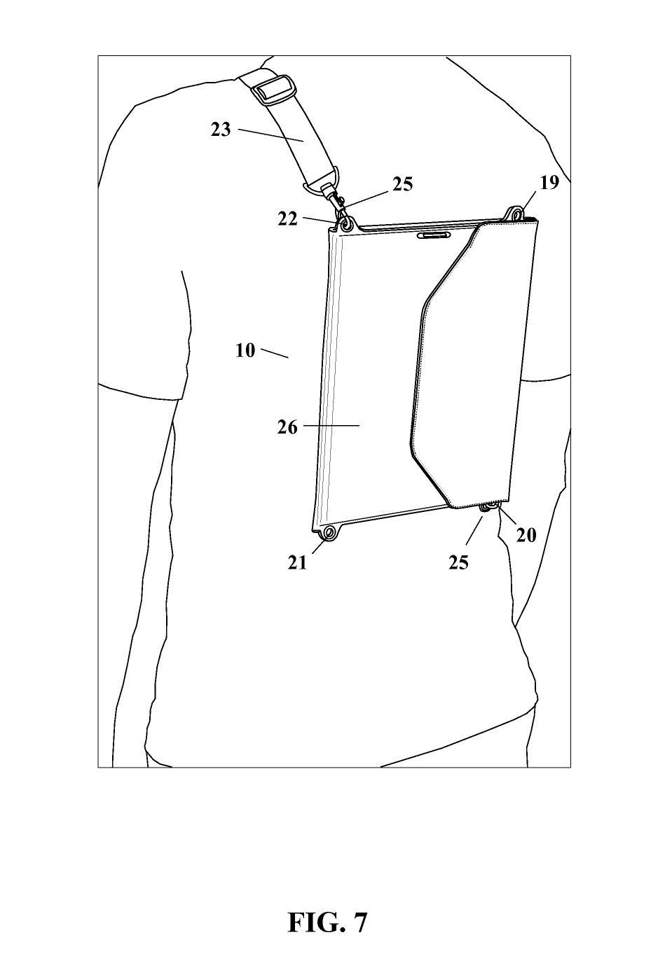

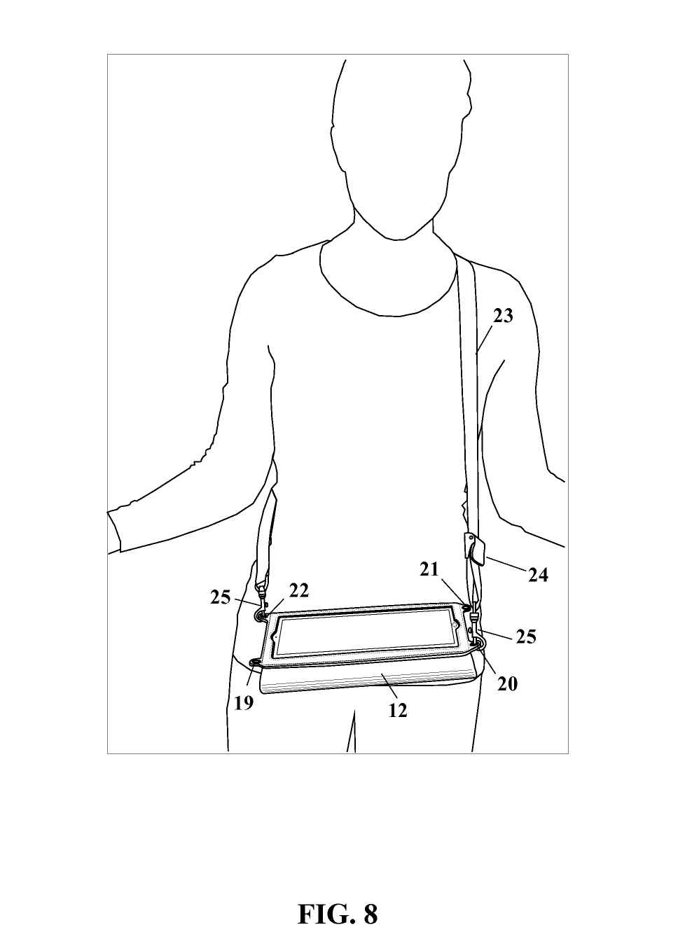

When the strap 23 is attached in the diagonal configuration to attachment points 19 and 21, or 20 and 22, the case can be carried across the back as a backpack (shown in FIG. 7). The case is easily convertible from backpack carrying mode into a hands-free platform mode (shown in FIG. 8). To convert the case; the user opens the sliding buckle 24 and slides it along the webbing of strap 23 to adjust the length, brings the case to the front of the body, detaches Velcro® strips 13 and 14, folds the flap 11 behind the case, reattaches Velcro® strips 13 and 14, and rests the case 10 against the body. The case is balanced as a result of the diagonal attachment strap configuration and the buttressing effect of the user's body. Hands-free mode allows the user easy access to the tablet display for data entry or viewing without the need to use either hand to support the tablet.

It is noted that any connection configuration that can provide the desired carrying position and/or hands-free mode may be used. The examples mentioned are only examples, and should not be seen as a limitation of the invention.

What is claimed is:

1. A lightweight carrying case streamlined for tablet use comprising at least:
a. a rectangular platform/back wall having an inside and outside surfaces;
b. a protective frame/border attached to the inside surface of the platform along the perimeter of the platform;
c. the platform and protective frame/border coupled to create a protective case to hold a tablet computer;
d. an opening in the front of the protective frame for the tablet display;
e. an opening/slot on the long side of the case between the platform and the protective frame to allow insertion of the tablet into the case in an envelope style method;
f. a flap connected to the long side of the platform that covers the screen, keeps the case closed, and can be used to configure the case as a stand;
g. four attachment points located at each corner of the platform;
h. a quickly adjustable strap that attaches to, and is releasable from, the four attachment points.

2. The carrying case of claim 1, wherein the quickly adjustable strap is utilized in conjunction with the four attachment points to allow the user to carry the tablet over the shoulder, across the chest, or across the back as a backpack, and convert the case into a hands-free wearable platform. The length of the strap is easily adjustable with a sliding cam buckle for quick transitions between configurations.

3. The carrying case of claim 1, wherein the quickly adjustable strap is detached to create a folio type case.

4. The carrying case of claim 1, wherein the flap is comprised of three sections to allow the case to be configured as a stand. One section that keeps the flap closed with Velcro® fasteners, a second section that protects the screen of the tablet and serves as vertical support in stand mode, and a third section that protects the screen of the tablet and serves as a horizontal support in stand mode.
